(19) United States
(12) Patent Application Publication
(10) Pub. No.: US 2024/0264121 A1
(43) Pub. Date: Aug. 8, 2024

(54) CYCLE LIFE PERFORMANCE DETERMINATION FOR BATTERIES USING ACOUSTIC SIGNAL ANALYSIS

(71) Applicant: Liminal Insights, Inc., Emeryville, CA (US)

(72) Inventors: Austin Ryan DULANEY, Emeryville, CA (US); Shaurjo BISWAS, El Cerrito, CA (US)

(73) Assignee: Liminal Insights, Inc., Emeryville, CA (US)

(21) Appl. No.: 18/431,153

(22) Filed: Feb. 2, 2024

Related U.S. Application Data
(60) Provisional application No. 63/482,877, filed on Feb. 2, 2023.

(51) Int. Cl. G01N 29/04

(52) U.S. Cl. CPC G01N 29/04; G01N 2291/023; G01N 2291/106

(57) ABSTRACT

Systems, techniques, and computer-implemented processes for cycle life performance determination of batteries using non-invasive acoustic solutions. In one aspect, a battery inspection system includes a plurality of transducers, and a controller communicatively coupled to the plurality of transducers. The controller is configured to send one or more commands to a first subset of the plurality of transducers for transmitting acoustic signals through a battery cell, receive, from a second subset of the plurality of transducers, response signals in response to the acoustic signals transmitted through the battery cell, and determine a cycle life performance score for the battery cell based on at least the response signals, the score indicating an estimated number of charge-discharge cycles that the battery cell goes through prior to reaching a threshold retention capacity.

### CROSS REFERENCE TO RELATED APPLICATIONS

This application claims the benefit of U.S. Provisional Application No. 63/482,877, filed on Feb. 2, 2023, and entitled “CYCLE LIFE PERFORMANCE DETERMINATION FOR BATTERIES USING ACOUSTIC SIGNAL ANALYSIS,” the content of which is hereby incorporated by reference in their entirety and for all purposes.

### FIELD OF DISCLOSURE

The present disclosure is directed to systems used for monitoring and inspection of batteries using acoustic signals. More specifically, exemplary aspects of the present disclosure are directed to determining cycle life performance for batteries based on acoustic signal analysis of battery cells.

### BACKGROUND

Demand for production of battery cells is on the rise owing to an increase in their use across various industries such as consumer electronics, automotive, clean energy, etc. Efficient and fast battery diagnostics methods are important for increasing quality, lifetime, and manufacturing process efficiency for batteries. In the case of manufacturing and production, reducing costs (e.g., price per kilowatt-hour (kWh)) is an important goal. Production costs and quality can be reduced by optimizing existing processes and/or introducing new technologies. For example, technological advances in the area of improved monitoring, manufacturing, and diagnostics can lead to cost efficiencies by shortening production process times (thus also reducing energy consumption during production), reducing waste due to damaged cells and cell parts, improving quality, etc.

### BRIEF DESCRIPTION OF THE DRAWINGS

The accompanying drawings are presented to aid in the description of various aspects of the disclosure and are provided solely for illustration and not limitation.

FIG. 1 illustrates an example system for analyzing a sample using acoustic signal-based analysis, according to some aspects of the present disclosure;

FIG. 2 illustrates another example system for analyzing a sample using acoustic signal-based analysis, according to some aspects of the present disclosure;

FIG. 3 illustrates an example process flow assessing performance of a battery cell at the end of a manufacturing process according to some aspects of the present disclosure;

FIG. 4 illustrates an example method of predicting future performance of battery cells according to some aspects of the present disclosure;

FIG. 5 illustrates an example neural network that can be utilized for predicting future performance of battery cells according to some aspects of the present disclosure;

FIGS. 6A and 6B provide a comparison of using electrical and acoustic inspection methods for predicting future performance of battery cells according to some aspects of the present disclosure; and

FIG. 7 illustrates an example computing device architecture of an example computing device, in accordance with some aspects of the disclosure.

### SUMMARY

Aspects of the present disclosure are directed to monitoring battery cells as they progress through the cell manufacturing process, module and pack manufacturing process, and/or as they are used during operation. Based on acoustic measurements of the battery cells through the manufacturing process and/or during the cycling process, their cycle life performance can be predicted. This prediction can be presented in a form of a cycle life performance score that indicates the expected number of charge/discharge cycles that a battery cell would go through before the battery cell fails/considered “dead.”

In one aspect, a method includes transmitting acoustic signals through a battery cell via one or more first transducers, receiving response signals in response to the acoustic signals at one or more second transducers, and determining a cycle life performance score for the battery cell based on at least the response signals, the score indicating an estimated number of charge-discharge cycles that the battery cell goes through prior to reaching a threshold retention capacity as a percentage of initial (or rated) capacity; or the likely retained capacity value after certain number of charge discharge cycles.

In another aspect, the method further includes determining one or more acoustic metrics indicative of one or more physical characteristics of the battery cell using the response signals.

In another aspect, the cycle life performance score is determined using a trained machine learning model.

In another aspect, the trained machine learning model receives, as input, at least the one or more acoustic metrics and provides, as output, the cycle life performance score.

In another aspect, the machine learning further receives, as input, at least one score, the at least one score being indicative of a physical quality of the battery cell after completion of at least one stage of a battery manufacturing process.

In another aspect, the at least one score includes one or more of a wetting score indicative of a soaking quality of the battery cell, a Solid Electrode Interphase (SEI) score indicative of a quality of SEI formation in the battery cell, an aging score indicative of a quality of aging of the battery cell, and a defect score indicative of presence of at least one physical defect in the battery cell.

In another aspect, the trained machine learning model further receives, as input, ground truth information on measured cycle life of one or more defect free battery cells corresponding to the battery cell.

In another aspect, the one or more acoustic metrics include localized material inhomogeneity, a ratio of structured material, a degree of acoustic similarity between the response signals, spread of acoustic character of the response signals, and spatial variation in material structure.

In another aspect, the acoustic signals are transmitted across a number of different locations of the battery cell.

In another aspect, the method further includes outputting the cycle life performance score on a graphical user interface.

In one aspect, a battery inspection system includes a plurality of transducers, and a controller communicatively coupled to the plurality of transducers. The controller is configured to send one or more commands to a first subset of the plurality of transducers for transmitting acoustic signals through a battery cell, receive, from a second subset of the plurality of transducers, response signals in response to the acoustic signals transmitted through the battery cell, and determine a cycle life performance score for the battery cell based on at least the response signals, the score indicating an estimated number of charge-discharge cycles that the battery cell goes through prior to reaching a threshold retention capacity.

In another aspect, the controller is further configured to determine one or more acoustic metrics indicative of one or more physical characteristics of the battery cell using the response signals.

In another aspect, the cycle life performance score is determined using a trained machine learning model.

In another aspect, the trained machine learning model receives, as input, at least the one or more acoustic metrics and provides, as output, the cycle life performance score.

In another aspect, the machine learning further receives, as input, at least one score, the at least one score being indicative of a physical quality of the battery cell after completion of at least one stage of a battery manufacturing process.

In another aspect, the at least one score includes one or more of a wetting score indicative of a soaking quality of the battery cell, a Solid Electrode Interphase (SEI) score indicative of a quality of SEI formation in the battery cell, an aging score indicative of a quality of aging of the battery cell, and a defect score indicative of presence of at least one physical defect in the battery cell.

In another aspect, the trained machine learning model further receives, as input, ground truth information on measured cycle life of one or more defect free battery cells corresponding to the battery cell.

In another aspect, the one or more acoustic metrics include localized material inhomogeneity, a ratio of structured material, a degree of acoustic similarity between the response signals, spread of acoustic character of the response signals, and spatial variation in material structure.

In another aspect, the acoustic signals are transmitted across a number of different locations of the battery cell.

In another aspect, the controller is further configured to output the cycle life performance score on a graphical user interface.

In another aspect, one or more non-transitory computer-readable media include computer-readable instructions, which when executed by one or more controllers of a battery inspection system, cause the one or more controllers to send one or more commands to a first subset of a plurality of transducers for transmitting acoustic signals through a battery cell, receive, from a second subset of the plurality of transducers, response signals in response to the acoustic signals transmitted through the battery cell, and determine a cycle life performance score for the battery cell based on at least the response signals, the score indicating an estimated number of charge-discharge cycles that the battery cell goes through prior to reaching a threshold retention capacity as a percentage of initial (or rated) capacity; or the likely retained capacity value after certain number of charge discharge cycles.

### DETAILED DESCRIPTION

Certain aspects and embodiments of this disclosure are provided in the following description and related drawings. Alternate aspects may be devised without departing from the scope of the disclosure. Additionally, well-known elements of the disclosure will not be described in detail or will be omitted so as not to obscure the relevant details of the disclosure.

The word “exemplary” is used herein to mean “serving as an example, instance, or illustration.” Any aspect described herein as “exemplary” is not necessarily to be construed as preferred or advantageous over other aspects. Likewise, the term “aspects of the present disclosure” does not require that all aspects of the disclosure include the discussed feature, advantage or mode of operation.

The terminology used herein is for the purpose of describing particular aspects only and is not intended to be limiting of aspects of the disclosure. As used herein, the singular forms “a,” “an,” and “the” are intended to include the plural forms as well, unless the context clearly indicates otherwise. It will be further understood that the terms “comprises”, “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequences of actions described herein can be considered to be embodied entirely within any form of computer readable storage medium having stored therein a corresponding set of computer instructions that upon execution would cause an associated processor to perform the functionality described herein. Thus, the various aspects of the present disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

Demand for production of battery cells is on the rise owing to an increase in their use across various industries such as consumer electronics, automotive, clean energy, etc. A non-limiting application of battery cells is the electrical vehicle (EV) industry. According to various market research, the industry needs massive buildouts to meeting EV demand by 2030 (around 15 times the current capacity). The cost of battery cell production should decrease by around 40% according to some estimates. Furthermore, as evidence thereof have already been seen, reliability of EV batteries is critical as human and financial remedies of EV recalls due to faulty batteries are immense (already to the tune of more than $3 B).

Battery manufacturing processes are not without challenges. For example, the cost of raw materials is on the rise. Issues during manufacturing can lead to poor quality battery cells and hence unreliable battery cell being incorporated into and utilized in their respective applications such as in EVs, which can ultimately lead to the costly failures mentioned above. Also, there is a significant time to obtain information about reliability of the manufacturing process and/or produced battery cells. For example, an error or deficiencies in processes used for electrode fabrication may not be detected until a battery cell is at the formation stage and after having gone through cell assembly, electrolyte filling, etc. Undoing that entire process for thousand to millions of battery cells is very costly.

Furthermore, battery manufacturers may alter one or more aspects or stages of their respective battery manufacturing processes. For instance, a battery manufacturer may, from time to time, test different wetting processes, formation processes, etc. A change in any of these processes may take months of testing and validation, which are also time consuming and costly.

Therefore, efficient and fast battery diagnostics methods are important for increasing quality, lifetime, and manufacturing process efficiency for batteries. Technological advances in improved monitoring, manufacturing, and diagnostics can lead to cost efficiencies by shortening production process times (thus also reducing energy consumption during production), reducing waste due to damaged cells and cell parts, improving quality, etc.

An example of battery diagnostic solution that addresses the shortcomings of existing solutions (e.g., electrical battery diagnostic solutions) and provide the aforementioned improvements, includes non-invasive and non-destructive analysis of battery cells using acoustic signal-based analysis, whereby acoustic signals are transmitted through one or more battery cells under testing and the received signals are analyzed using various known or to be developed data analytics techniques to assess the physical properties of battery cells and components thereof including state of health, state of charge, battery cell life expectancy, etc. Data analytics on signals obtained by ultrasound propagation through materials inside battery cells can be used to analyze electrode slurry parameters including slurry density, trapped air content, viscosity, and uniformity of mixture. In some examples, using the disclosed techniques in battery manufacturing and production can lead to reduction in waste of damaged/scrapped battery cells and shorten production time.

The example non-invasive and acoustic processes of the present disclosure rely on transmission and reception of acoustic signals through battery cell(s) under testing. The transmission and reception of acoustics signals are enabled using one or more arrays of transducers structured and configured to operate as transmitters and/or receivers of acoustic signals.

Existing standard inspection methods such as electrical methods are limited in terms of the insight they can provide. For example, they can only provide 1-dimensional and cell-averaged information as opposed to cell-specific insights for practically every battery cell that is ultimately produced. They are also very limited and provide time-consuming processes for detecting process issues and in predicting quality during production.

On the other hand, acoustic inspection methods disclosed herein can provide fast (in a matter of seconds), non-invasive physical inspection of any type of battery cell. They provide 2-dimensional and spatially resolved data that are sensitive to internal inhomogeneities within each battery cell, and they deliver powerful insights about the quality of each battery cell during production.

As will be described in more detail below, acoustic inspection methods of the present disclosure can be utilized to monitor battery cells as they progress through the manufacturing process. Based on acoustic measurements of the battery cells, their cycle life performance can be predicted. This prediction can be presented in a form of a cycle life performance score (e.g., a predicted number of cycles that a battery cell is charged before the battery cell is considered “dead” or “unusable” for its purpose, which according to industry standards is close to when a battery cell reaches 80% of its nominal capacity).

In some examples, one or more machine learning techniques and trained neural networks may be utilized where acoustic features representative of physical characteristics of battery cells and their component can be input into trained neural networks, along with some “ground truth,” and a predicted cycle life of the battery cells is provided as an output in the form of a cycle life performance score.

Throughout the present disclosure, reference is made to a battery cell. However, the present disclosure is not limited to inspection of one battery cell at a time and may be equally applicable to inspection of batteries formed of two or more battery cells. A battery can be a single cell battery or a multi-cell battery. A battery in the context of the present disclosure may refer to a battery cell, a multi-cell battery, a battery pack, and/or a module consisting of multiple batteries.

The disclosure begins with a description of example systems used for acoustic signal analysis of batteries.

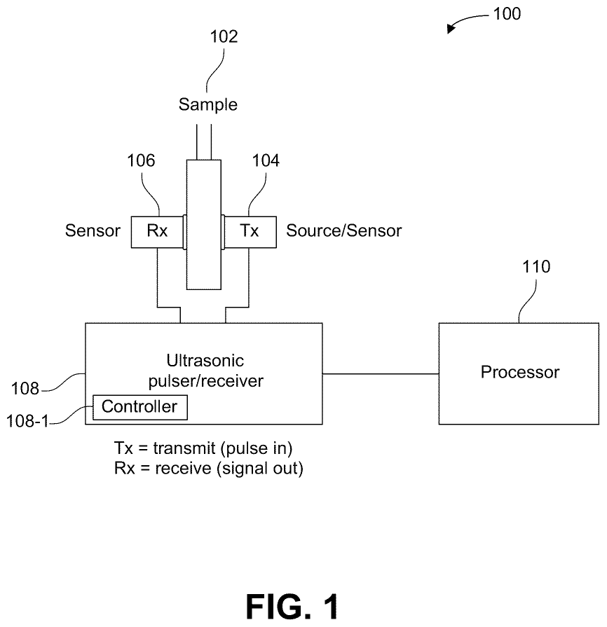

FIG. 1 illustrates an example system for analyzing a sample using acoustic signal-based analysis, according to some aspects of the present disclosure. System 100 may include sample 102. Sample 102 can include a battery cell or component thereof in any stage of production or manufacture of the battery cell or the individual components. In some examples, sample 102 can include a battery cell, electrolytes in various stages of wetting/distribution through a battery cell, one or more electrodes of the battery cell, thin films, separators, coated sheets, current collectors, electrode slurries, or materials for forming any of the above components during any stage of their formation. System 100 can include a transmitting transducer Tx 104 or other means for sending excitation sound signals into the battery cell (e.g., for transmitting a pulse or pulses of ultrasonic or other acoustic waves, vibrations, resonance measurements, etc., through the battery cell). System 100 can further include a receiving transducer Rx 106 or other means for receiving/sensing the sound signals, which can receive response signals generated from signals transmitted by Tx transducer 104. Any type of known or to be developed transducer for transmitting and receiving acoustic signals may be used as Tx transducer 104. Transmitted signals from Tx transducer 104, from one side of sample 102 on which Tx transducer 104 is located, may include input excitation signals. Reflected signals, e.g., from another side of sample 102, may include echo signals. It is understood that references to response signals may include both the input excitation signals and the echo signals. Further, Tx transducer 104 may also be configured to receive response signals, and similarly, Rx transducer 106 may also be configured to transmit acoustic signals. Any type of known or to be developed transducer for transmitting and receiving acoustic signals may be used as Rx transducer 106. Therefore, even though separately illustrated as Tx and Rx, the functionalities of these transducers may be for both sending and receiving acoustic signals. In various alternatives, even if not specifically illustrated, one or more Tx transducers and one or more Rx transducers can be placed on the same side or wall of sample 102, or on different (e.g., opposite) sides. Throughout this disclosure, reference may be made to a transducer pair (a transmitting transducer and a receiving transducer). Transducer Tx 104 and transducer Rx 106 may form a pair of transducers.

Acoustic pulser/receiver 108 can be coupled to Tx and Rx transducers 104, 106 for controlling the transmission of acoustic signals (e.g., ultrasound signals) and receiving response signals. Acoustic pulser/receiver 108 may include a controller 108-1 for adjusting the amplitude, frequency, and/or other signal features of the transmitted signals. Acoustic pulser/receiver 108 may also receive the signals from Rx transducers 106. In some examples, acoustic pulser/receiver 108 may be configured as a combined unit, while in some examples, an acoustic pulser for transmitting excitation signals through Tx transducer 104 can be a separate unit in communication with a receiver for receiving signals from Rx transducer 106. Processor 110 in communication with acoustic pulser/receiver 108 may be configured to store and analyze the response signal waveforms according to this disclosure. Although representatively shown as a single processor, processor 110 can include one or more processors, including remote processors, cloud computing infrastructure, etc.

Although not explicitly shown in FIG. 1, more than one Tx transducer and/or more than one Rx transducer can be placed in one or more spatial locations across sample 102. This allows studying a spatial variation of acoustic signal features across sample 102. A multiplexer can be configured in communication with the acoustic pulser/receiver 108 for separating and channeling the excitation signals to be transmitted and the response signals received. In some examples, various acoustic couplants can be used (e.g., solid, liquid, or combinations thereof) for making or enhancing contact between Tx and Rx transducers 104, 106 and sample 102. Furthermore, various attachment or fixturing mechanisms (e.g., pneumatic, compression, screws, springs etc.) can also be used for establishing or enhancing the contact between Tx and Rx transducers 104, 106 and sample 102.

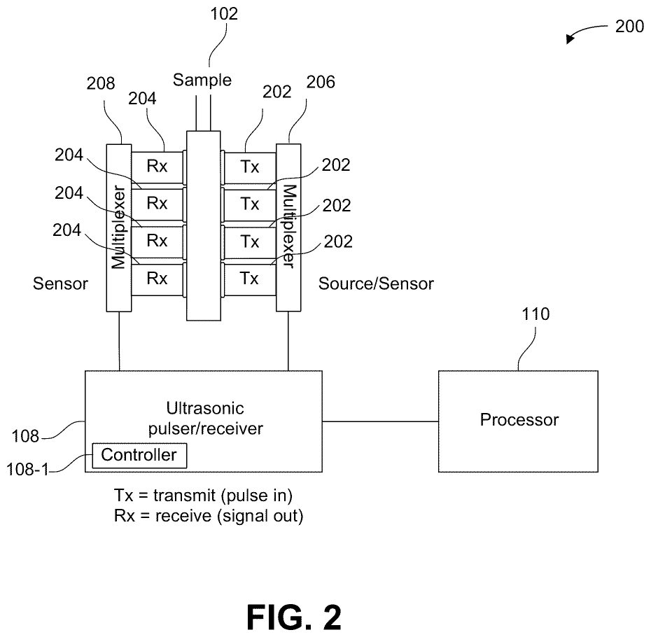

FIG. 2 illustrates another example system for analyzing a sample using acoustic signal-based analysis, according to some aspects of the present disclosure. In comparison with FIG. 1, system 200 of FIG. 2 illustrates a system in which multiple pairs of transmitting and receiving transducers are used for transmitting signals through a sample under testing (e.g., a battery cell) and performing acoustic signal-based analysis of the sample.

System 200 includes several transmitting Tx transducers 202 (each of which may be the same as Tx transducer 104 of FIG. 1). While an array of four examples Tx transducers 202 are shown in FIG. 2, the disclosure is not limited to four. Any number of transducers may be used (e.g., any number of Tx transducers ranging from 1 to 10, 15, 20, etc.).

Similarly, system 200 includes a number of receiving (sensing) Rx transducers 204 (each of which may be the same as Rx transducer 106 of FIG. 1). While an array of four examples Rx transducers 204 are shown in FIG. 2, the disclosure is not limited to four. Any number of transducers may be used (e.g., any number of Rx transducers ranging from 1 to 10, 15, 20, etc.). Any given Tx transducer 202 and Rx transducer 204 may form a transducer pair (FIG. 2 illustrates four transducer pairs). FIG. 2 also illustrates a multiplexer 206 coupled to the array of four Tx transducers 202 and a multiplexer 208 coupled to the array of four Rx transducers 204. As described above, each one of multiplexers 206 and 208 may be configured in communication with the acoustic pulser/receiver 108 for separating and channeling the excitation signals to be transmitted and the response signals received, respectively. In some examples, various acoustic couplants can be used (e.g., solid, liquid, or combinations thereof) for making or enhancing contact between Tx and Rx transducers 202, 204 and sample 102. Furthermore, various attachment or fixturing mechanisms (e.g., pneumatic, compression, screws, etc.) can also be used for establishing or enhancing the contact between Tx and Rx transducers 202, 204 and sample 102.

Spacing between Tx transducers 202 and Rx transducers 204 may be uniform and the same. System 200 also includes additional elements such as sample 102, ultrasonic pulser/receiver 108 (controller 108-1), processors 110, each of which may be the same as the corresponding counterpart described above with reference to FIG. 1 and hence will not be described further for sake of brevity.

With example systems used for acoustic signal analysis of batteries described with reference to FIGS. 1 and 2, the disclosure now turns to example methods of determining cycle life performance (future performance) of battery cells based on acoustic measurements representative of their physical characteristics as they progress through the manufacturing process.

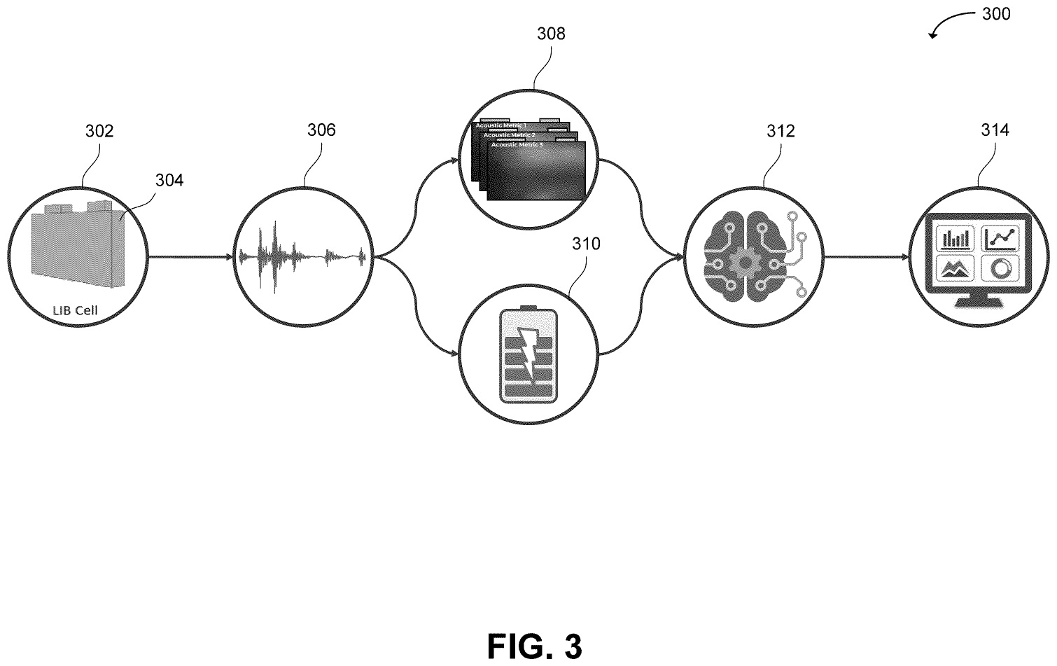

FIG. 3 illustrates an example process flow assessing performance of a battery cell at the end of a manufacturing process according to some aspects of the present disclosure.

A manufacturing process of a battery cell typically includes a number of stages such as wetting, formation, aging, etc. Completion of the aging process may be referred to as the end of the production line. These processes and the end of production may be referenced in describing FIGS. 3-6A-B.

Example process 300 of FIG. 3 has several stages. The first stage may be stage 302 where a battery cell 304 may undergo acoustic measurements. Battery cell 304 may be a Lithium-Ion Battery (LIB) cell. The acoustic measurements may be taken using example systems described above with reference to FIGS. 1 and 2. Battery cell 304 may be at the end of the production line or may have completed any of the intermediary stages of the production such as wetting, formation, aging, etc.

Stage 306 of process 300 may involve analyzing acoustic signals transmitted through each point of battery cell 304 and received there though. Any known or to be developed signal pre-processing and analysis methodologies may be applied at this stage.

Based on the results of the signal analysis performed, at stage 308, meaningful acoustic metrics indicative of physical characteristics of battery cell 304 may be obtained. Such physical characteristics include, but are not limited to, quality of SEI formation, presence of defects, quality of the electrolyte filling, etc.

Stage 310 may be a stage where one or more battery cells (which may or may not include battery cell 304) undergoes a cycling process. In one example, the one or more battery cells that undergo such cycling process may be “perfect” cells. A “perfect” cell may be defined as one that is free of physical defects and/or otherwise any other type of defect that may undermine its long-term performance, cause the battery cell to short, unexpectedly fail, etc. Such “perfect” cells may undergo a typical cycling process (e.g., the battery is charged and discharged until the battery cell reaches a threshold retention capacity such as 80% of its retention capacity at which point the battery cell fails/is considered “unusable” or “dead.”).

Stage 310 may be performed independently of remaining stages of process 300 and not necessarily in parallel therewith. For instance, every predetermined period of time, a batch of “perfect” cells may be selected to undergo the cycling process. As the cycling process is typically a time-consuming process (e.g., can take up to a year), the predetermined period of time may be selected accordingly (e.g., once a year, once every six months, etc.).

In one example, at any given point in time, a database of cycled “perfect” cells may exist that includes ground truth information for “perfect” battery cells of different types, shapes, material (e.g., Lithium-Ion, Lithium-Metal, etc.), battery cells having gone through specific manufacturing processes (e.g., specific wetting processes, specific formation processes, specific aging processes, etc.).

Therefore, depending on the specific characteristics of battery cell 304, ground truth information of one or more “perfect” cells having same or similar characteristics (e.g., types, shapes, material, similar manufacturing processes, etc.) as battery cell 304, may be selected and provided as input into a trained machine learning model along with the meaningful acoustic metrics of stage 308, to be processed at stage 312.

At stage 312, and as will be described in more detail below, a trained machine learning model, may be deployed that receives as input, the acoustic features of stage 308 and relevant ground truth information of stage 310. The inputs are processed, and the trained machine learning model can provide as output, a Cycle Life Performance (CLP) score. This score is a predicted number of charge cycles that battery cell 304 may go through before reaching the threshold retention capacity (e.g., 80% of its retention capacity). The score may also be a predicted retention capacity at a given threshold number of charge cycles (e.g., 500 cycles). The score then can range from 0 to 1 if nominal capacity is used or slightly higher if rated capacity is the metric for evaluation. As will be further described below, the CLP score can range from 0 to 2000, 2500, 3000, etc.

In some examples, the trained machine learning model, may identify extreme values in the acoustic measurements (e.g., greater than or equal to a configurable threshold or less than or equal to a configurable threshold) to flag points in battery cell 304 that may be faulty. This detection is then used for determining a CLP score. In other words, extreme values may be indicative of faulty points in the battery, which can in turn result in a lower CLP score for battery cell 304.

In one example, one or more parameters may be provided as additional inputs into the trained machine learning model. Examples of these additional inputs include, but are not limited to, a wetting score, a formation score, a defect detection s core, an aging score, etc. Such scores may be determined according to various non-invasive and acoustic-based solutions by which battery cell 304 may be examined during the wetting stage, formation stage, aging stage, etc. during battery manufacturing, or after certain number of charge discharge cycles (e.g. 1, 100, 500, etc. cycles) during battery operation.

In one example, CLP score may be provided as an actionable insight output at stage 314. CLP score may be an actionable insight because it can allow a battery manufacturer to classify a given battery cell based on the CLP score. In one example, battery cells having a threshold CLP score may be designated for a specific application. For example, battery cells having CLP scores of at least 2000 may be designated for EV applications or specific customers within the EV space. In another example, battery cells having CLP scores in the range of 1500-2000 may be designated for another group of specific customers within the EV space or for consumer electronic applications, etc.

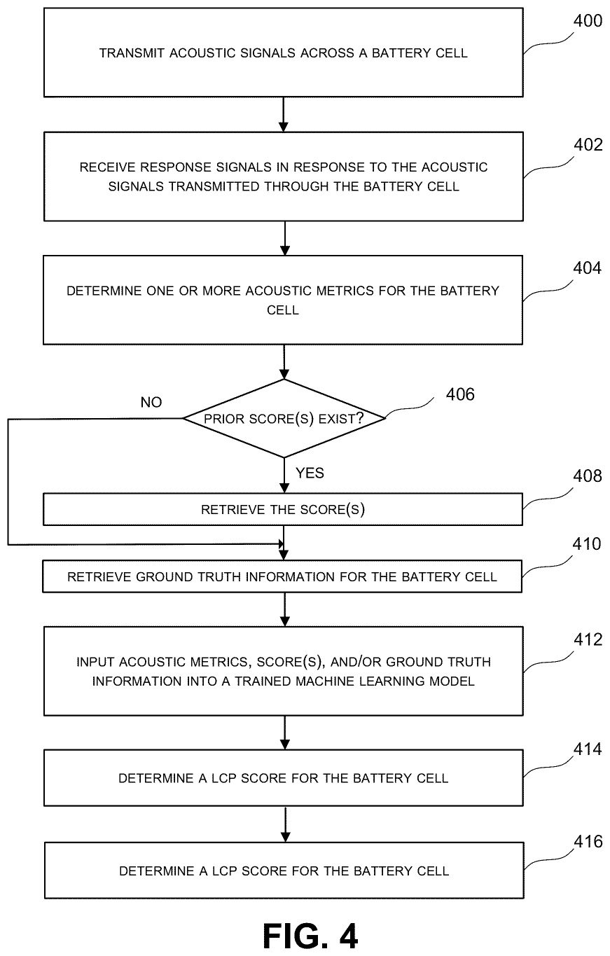

FIG. 4 illustrates an example method of predicting future performance of battery cells according to some aspects of the present disclosure. The process of FIG. 4 will be described with reference to FIGS. 1-3. Furthermore, process of FIG. 4 will be described from the perspective of a controller such as processor 110 described with reference to FIGS. 1 and 2. However, the present disclosure is not limited thereto, and the process of FIG. 4 can be performed by any other processor that is communicatively coupled to one or more systems configured to acoustically inspect battery cells as they progress through the manufacturing process. Such processors may be cloud based and/or otherwise remotely located with respect to the inspection systems and communicatively coupled thereto.

At step 400, a controller may send one or more commands to one or more transmitters (e.g., transducer 104 and/or transducers 202) for transmitting acoustic signals through a battery cell such as battery cell 304, sample 102, etc.

In some examples, battery cell 304 through which the acoustic signals are transmitted is at the end of the production line (e.g., has completed the different stages of battery cell manufacturing such as wetting, formation, aging, etc.).

At step 402, the controller may receive response signals in response to the acoustic signals transmitted through the battery cell. The response signals may be received from one or more receiving transducers such as transducer 106 and/or transducers 204.

In some example embodiments, transmission of the one or more commands at step 400 may be automatically triggered upon detection of an event such as placement of battery cell 304 at a designated position in between transmitting and receiving transducers such as transducers 104/106 and/or transducers 202/204.

At step 404, the controller may analyze the received response signals to determine one or more acoustic metrics associated with battery cell 304. In some examples, the one or more acoustic metrics may be indicative of one or more physical properties of battery cell 304 having completed one or more stages of a battery manufacturing process. Non-limiting examples of such acoustic metrics include localized material inhomogeneity, a ratio of structured material, a degree of acoustic similarity between the response signals, spread of acoustic character of the response signals, and spatial variation in material structure.

An example process utilized for analyzing acoustic signals and extracting meaningful acoustic metrics at step 404, is described in U.S. application Ser. No. 17/112,756 filed on Jul. 6, 2021, the entire content of which is incorporated herein by reference.

At step 406, the controller may determine whether any prior score for battery cell 304 exists. As battery cell 304 progresses through different stages of the manufacturing process, one or more acoustic inspection systems such as systems 100/200 may be used to determine the quality of the particular process completed at that stage. For example, a system such as system 100/200 may be used to determine the quality of wetting for battery cell 304 after battery cell 304 completes the wetting process.

A wetting score may provide a snapshot of the quality of the wetting process and electrolyte distribution/soaking quality for battery cell 304. In one example, a wetting score may be determined as described in U.S. patent application Ser. No. 16/826,718 filed on Mar. 23, 2020, the entire content of which is incorporated herein by reference.

Similarly, a formation score can indicate a quality of Solid Electrode Interphase (SEI) formation of battery cell 304 during the formation stage. In one example, a formation score may be determined based on acoustic signals transmitted through on or more locations of a battery cell after completion of the SEI formation.

An aging score may be determined for battery cell 304 after battery cell 304 completes the aging stage.

A defect detection score may indicate presence of one or more physical defects in component(s) of battery cell 304, presence of foreign object(s) inside battery cell 304, etc. In one example, defect detection may be performed as described with in U.S. Provisional Application No. 63/309,975 filed on Feb. 14, 2022 and U.S. Provisional Application No. 63/309,978 filed on Feb. 14, 2022, the entire content of both which is incorporated herein by reference.

In some examples, a defect detection analysis for determining a defect detection score may be performed after the aging stage and/or after completion of any of the stages prior to the aging stage.

If at step 406, the controller determines that one or more prior scores for battery cell 304 exist, then at step 408, the controller retrieves the one or more scores. If no prior score exists, the process proceeds to step 412, which will be described below.

At step 410, the controller may retrieve relevant ground truth information for battery cell 304. The ground truth information, as described above, may refer to data associated with performance of one or more battery “perfect” cells that are similar to battery cell 304 and have gone through charge/discharge cycling for determining their expected number of charge cycles before they reach the threshold retention capacity (e.g., 80%). A “perfect” cell may be considered similar to battery cell 304 if the “perfect” cell is of the same type as battery cell 304, if the “perfect” cell has gone through similar manufacturing processes as battery cell 304, etc.

In some examples, the ground truth information may be retrieved from a database in which the ground truth information are stored and is communicatively coupled to the controller.

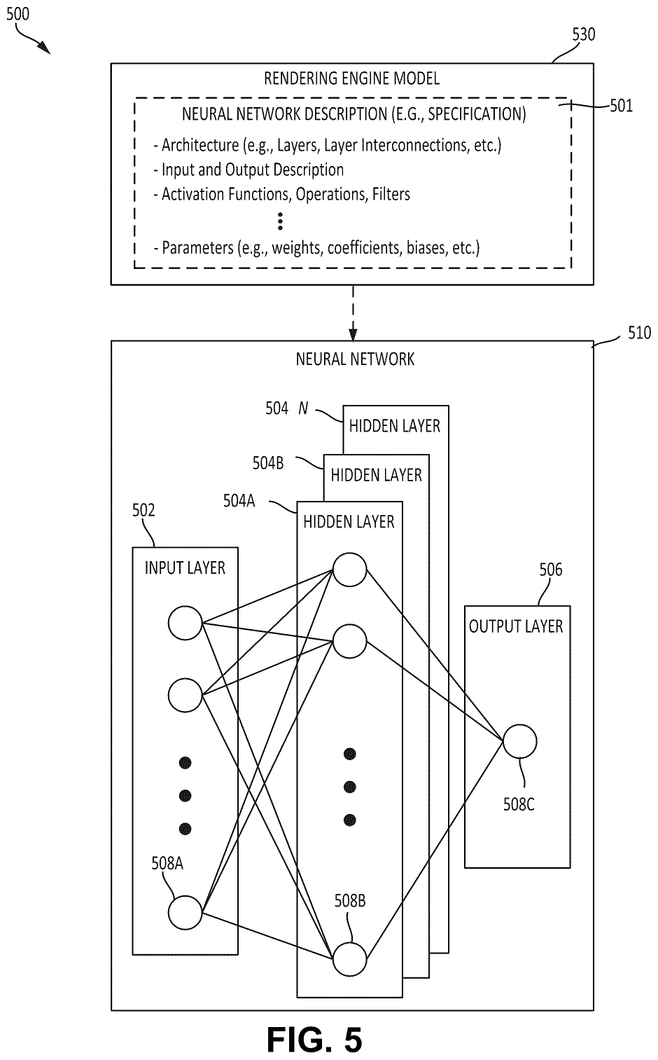

At step 412, the controller may provide as input into a trained machine learning model, the acoustic metrics determined at step 404, any prior score(s) retrieved at step 408 (if any), and the ground truth information retrieved at step 410. An example trained machine learning model will be described below with reference to FIG. 5.

At step 414 and using the trained machine learning model, the controller may determine a CLP score for battery cell 304. As noted above, the CLP score is a predicted performance of battery cell 304 in the future (e.g., after battery cell 304 is placed in use for its underlying application such as in an EV, in a consumer electronic device, etc.).

At step 416, the CLP score may be provided as output (an actionable insight) on a user interface (e.g., a monitor at a terminal via which systems 100/200 are controlled by an operator, etc.).

FIG. 5 illustrates an example neural network that can be utilized for predicting future performance of battery cells according to some aspects of the present disclosure.

Architecture 500 includes a neural network 510 defined by an example neural network description 501 in rendering engine model (neural controller) 530. Neural network 510 can be used for determining a CLP score for battery cell 304 as described above with reference to FIG. 4. Neural network description 501 can include a full specification of neural network 510. For example, neural network description 501 can include a description or specification of the architecture of neural network 510 (e.g., the layers, layer interconnections, number of nodes in each layer, etc.); an input and output description which indicates how the input and output are formed or processed; an indication of the activation functions in the neural network, the operations or filters in the neural network, etc.; neural network parameters such as weights, biases, etc.; and so forth.

In this example, neural network 510 includes an input layer 502, which can receive input data including, but not limited to, acoustic metrics for a given battery cell measured via acoustic signals transmitted therethrough as described above with reference to step 406 of FIG. 4, one or more scores for battery cell 304 as described above with reference to step 408 of FIG. 4, and/or ground truth information retrieved at step 410 of FIG. 4.

Neural network 510 includes hidden layers 504A through 504N (collectively “504” hereinafter). Hidden layers 504 can include n number of hidden layers, where n is an integer greater than or equal to one. The number of hidden layers can include as many layers as needed for a desired processing outcome and/or rendering intent. Neural network 510 further includes an output layer 506 that provides as output, an CLP score for battery cell 304. As described above, an CLP score is a predicted number (estimated number) of charge/discharge cycles that battery cell 304 is likely to go through before it reaches a threshold retention capacity (e.g., 80%), beyond which battery cell 304 is considered “dead” or “unusable” for its underlying application. In other words, the output CLP score is indicative of a predicted future performance of battery cell 304 when battery cell 304 leaves the end of the manufacturing line and put to use in an underlying application (e.g., in an EV, in a mobile phone, etc.).This output may be based on processing performed by hidden layers 504.

Neural network 510 in this example is a multi-layer neural network of interconnected nodes. Each node can represent a piece of information. Information associated with the nodes is shared among the different layers and each layer retains information as information is processed. In some cases, neural network 510 can include a feed-forward neural network, in which case there are no feedback connections where outputs of the neural network are fed back into itself. In other cases, neural network 510 can include a recurrent neural network, which can have loops that allow information to be carried across nodes while reading in input.

Information can be exchanged between nodes through node-to-node interconnections between the various layers. Nodes of input layer 502 can activate a set of nodes in first hidden layer 504A. For example, as shown, each of the input nodes of input layer 502 is connected to each of the nodes of first hidden layer 504A. The nodes of hidden layer 504A can transform the information of each input node by applying activation functions to the information. The information derived from the transformation can then be passed to and can activate the nodes of the next hidden layer (e.g., 504B), which can perform their own designated functions. Example functions include convolutional, up-sampling, data transformation, pooling, and/or any other suitable functions. The output of the hidden layer (e.g., 504B) can then activate nodes of the next hidden layer (e.g., 504N), and so on. The output of the last hidden layer can activate one or more nodes of output layer 506, at which point an output is provided. In some cases, while nodes (e.g., nodes 508A, 508B, 508C) in neural network 510 are shown as having multiple output lines, a node has a single output and all lines shown as being output from a node represent the same output value.

In some cases, each node or interconnection between nodes can have a weight that is a set of parameters derived from training neural network 510. For example, an interconnection between nodes can represent a piece of information learned about the interconnected nodes. The interconnection can have a numeric weight that can be tuned (e.g., based on a training dataset), allowing neural network 510 to be adaptive to inputs and able to learn as more data is processed.

Neural network 510 can be pre-trained to process the features from the data in the input layer 502 using the different hidden layers 504 in order to provide the output through output layer 506. In this example, neural network 510 can be trained using training data that includes prior CLP scores determined for battery cells with varying physical characteristics, past analysis of correlations between different physical features and expected and/or actual performance of battery cells, data on performance of battery cells as measured by existing electrical inspection methods, etc.

In one or more examples, training of neural network 510 may be supervised, whereby the model is trained using labeled datasets whereby one or more aspects of neural network 510, such as weights, biases, etc., are tuned until neural network 510 returns the expected result for a given type of battery cell. In other examples, the training may be unsupervised.

In some examples, the training may be based on zero-shot learning and/or transfer learning.

In some cases, neural network 510 can adjust weights of nodes using a training process called backpropagation. Backpropagation can include a forward pass, a loss function, a backward pass, and a weight update. The forward pass, loss function, backward pass, and parameter update is performed for one training iteration. The process can be repeated for a certain number of iterations for each set of training media data until the weights of the layers are accurately tuned.

For a first training iteration for neural network 510, the output can include values that do not give preference to any particular class due to the weights being randomly selected at initialization. For example, if the output is a vector with probabilities that the object includes different product(s) and/or different users, the probability value for each of the different product and/or user may be equal or at least very similar (e.g., for ten possible products or users, each class may have a probability value of 0.1). With the initial weights, neural network 510 is unable to determine low level features and thus cannot make an accurate determination of what the classification of the object might be. A loss function can be used to analyze errors in the output. Any suitable loss function definition can be used.

The loss (or error) can be high for the first training dataset (e.g., images) since the actual values will be different than the predicted output. The goal of training is to minimize the amount of loss so that the predicted output comports with a target or ideal output. Neural network 510 can perform a backward pass by determining which inputs (weights) most contributed to the loss of neural network 510 and can adjust the weights so that the loss decreases and is eventually minimized.

A derivative of the loss with respect to the weights can be computed to determine the weights that contributed most to the loss of neural network 510. After the derivative is computed, a weight update can be performed by updating the weights of the filters. For example, the weights can be updated so that they change in the opposite direction of the gradient. A learning rate can be set to any suitable value, with a high learning rate including larger weight updates and a lower value indicating smaller weight updates.

Neural network 510 can include any suitable neural or deep learning network. One example includes a convolutional neural network (CNN), which includes an input layer and an output layer, with multiple hidden layers between the input and out layers. The hidden layers of a CNN include a series of convolutional, nonlinear, pooling (for downsampling), and fully connected layers. In other examples, neural network 510 can represent any other neural or deep learning network, such as an autoencoder, a deep belief network (DBN), a recurrent neural network (RNN), etc.

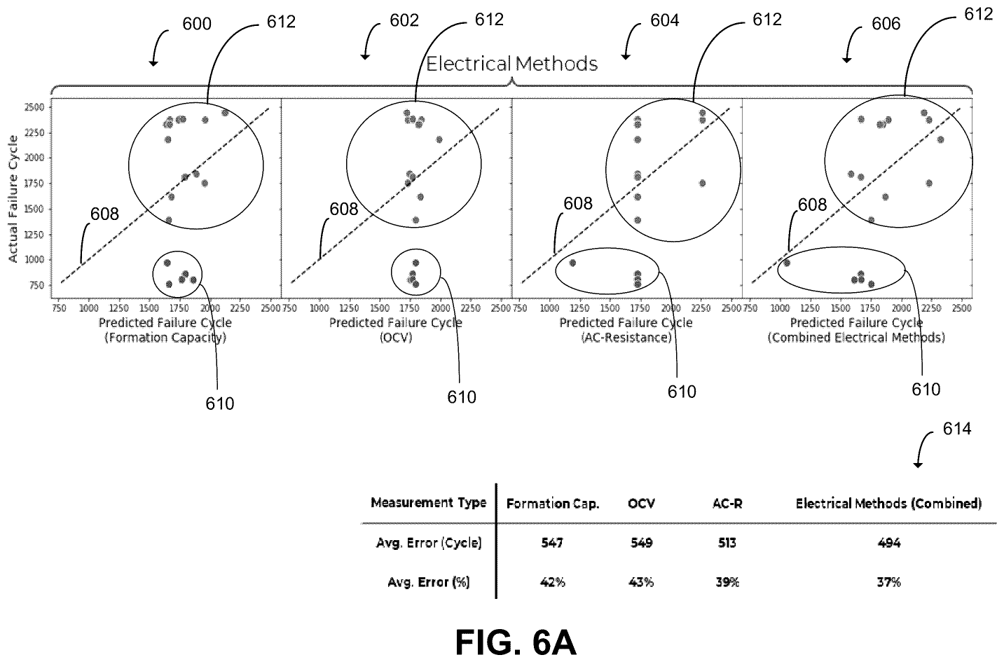

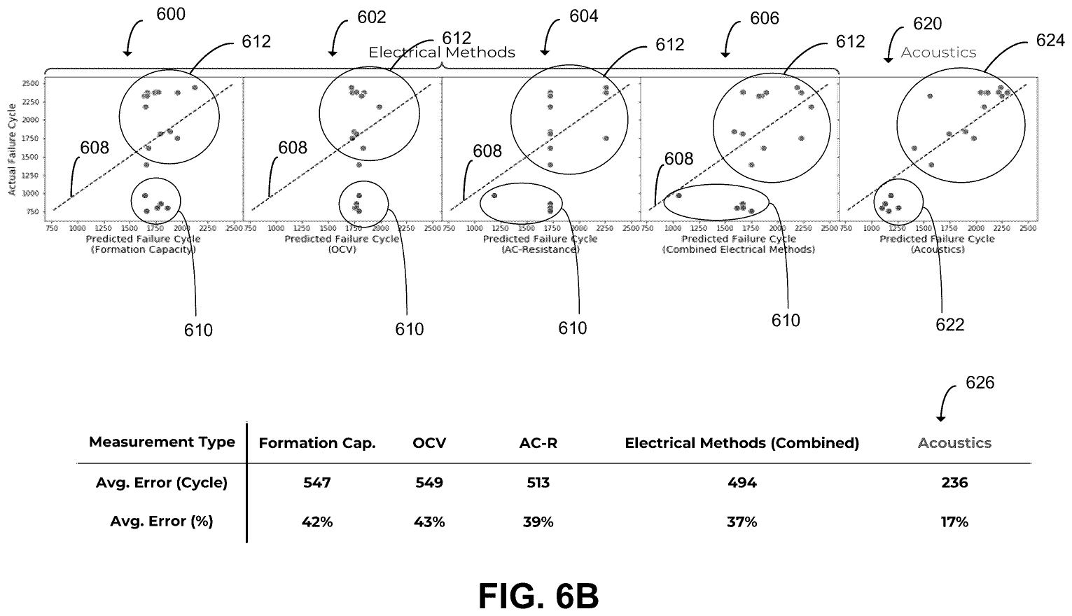

FIGS. 6A and 6B provide a comparison of using electrical and acoustic inspection methods for predicting future performance of battery cells according to some aspects of the present disclosure.

In FIG. 6A, four graphs 600, 602, 604, and 606 are shown where four electrical methods (e.g., Formation Capacity, Open Circuit Voltage (OCV), AC-Resistance, and a combination of Formation Capacity, OCV and AC-Resistance) used for predicting a cycle for battery cells are compared. In graphs 600, 602, 604, and 606, the term failure cycle is used instead of cycle life but conveys the same (i.e., how many charge/discharge cycles a battery cell goes through before failing/being considered “dead”).

Graph 600 illustrates a predicted failure cycle for several batteries plotted versus the actual/measured failure cycle using formation capacity method. In other words, the formation capacity method predicts a number of charge/discharge cycles that each plotted battery cell is likely to go through before failing (e.g., reaching a threshold retention capacity) versus the actual/measured number of charge/discharge cycles that the same battery cells went through before failing.

Graph 602 is showing the same predicted versus actual failure cycle for the OCV method. Graph 604 is showing the same predicted versus actual failure cycle for the AC-Resistance method. Graph 606 is showing the same predicted versus actual failure cycle for the combination of Formation Capacity, OCV, and AC-Resistance methods.

Each of graphs 600, 602, 604, and 606 have a line 608, which in an ideal world would indicate a one-to-one corresponding between predicted cycle life and actual cycle life of the subject battery cells.

Each of graphs 600, 602, 604, and 606 illustrate two groups of plotted battery cells. One is group 610 and the other is group 612. Group 610 on each graph includes battery cells that experienced an unexpected failure, after actual measurement, due to an underlying fault or problem (e.g., existence of a physical defect, uneven SEI formation, uneven electrolyte distribution, etc.). For these battery cells in group 610, the underlying electrical method used for predicting their respective cycle life did not work as expected. Group 612 on each graph designates battery cells where the predicted cycle life was approximately the same as the actual cycle life (the underlying prediction method worked as expected).

Table 614 in FIG. 6A compares the performance of each electrical inspection method and the error percentage associated with each. As one can see from table 614, the outcome or effectiveness of each electrical method is close to or slightly better than 50%. In other words, the performance of the electrical methods is slightly better than a simple guessing of what the predicted future performance of a battery cell is. The performance of a combination of the electrical methods presents a marginal improvement over individual electrical methods (5% or less).

FIG. 6B illustrates another example where acoustic inspection solution of the present disclosure is compared to existing electrical methods for predicting future performance of battery cells.

In FIG. 6B, graph 620 plotting predicted v. actual cycle life of battery cells along with graphs 600, 602, 604, and 606, is shown. Group 622 includes faulty battery cells similar to group 610 while group 624 includes battery cells with expected cycle life similar to group 612.

Table 626 illustrates the improvement in predicted future performance of battery cells achieved using the acoustic solutions of the present disclosure with an error rate of 17%, which is significantly less than that of the electrical methods, individually or combined.

The results shown in FIGS. 6A and 6B are for Lithium-Ion batteries. In other instances, test results further indicate that around the same reduction in error rate can be achieved for other cell chemistries including, but not limited to, Lithium-Metal batteries.

Therefore, the acoustic solutions of the present disclosure enable battery manufacturers to determine/predict, within a couple of seconds, cycle life of a battery cell through the CLP score and detect faulty battery cells early on. The detection of faulty battery cells can allow the manufacture to take a number of actions such as (1) removing those from the batch and disposing of them, (2) identify a problem with a particular stage of the battery manufacturing process, (3) modify any stage of the manufacturing process and quickly observe the effect of a change in the relevant process (e.g., wetting, formation, aging, etc.) on the future performance of the battery cells and make any necessary changes/adjustments, etc.

While determining a CLP score has been described in the context of a battery cell progressing through or having completed the manufacturing process, the present disclosure is not limited thereto. In some examples, CLP score determination may be applied to determine/predict performance of a battery during operations and/or otherwise during the entire life-cycle of the battery cell/battery module/battery pack. Doing so, may enable entities using the manufactured batteries (e.g., EV/device makers and EV/device users) to detect faulty battery cells early and service poor performing batteries after the battery cells are put into use.

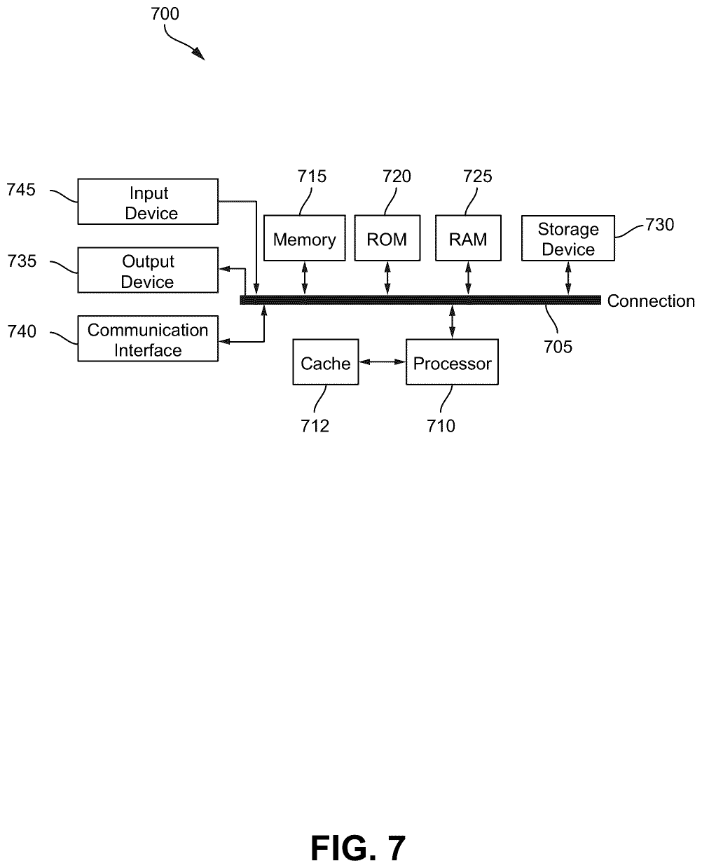

FIG. 7 illustrates an example computing device architecture of an example computing device, in accordance with some aspects of the disclosure. Device architecture 700 of an example computing device which can be used as various components of system 100 or 200 (e.g., processor 110) implement various techniques described herein. The components of the computing device architecture 700 are shown in electrical communication with each other using a connection 705, such as a bus. The example computing device architecture 700 includes a processing unit (CPU or processor) 710 and a computing device connection 705 that couples various computing device components including the computing device memory 715, such as read only memory (ROM) 720 and random access memory (RAM) 725, to the processor 710.

The computing device architecture 700 can include a cache of high-speed memory connected directly with, in close proximity to, or integrated as part of the processor 710. The computing device architecture 700 can copy data from the memory 715 and/or the storage device 730 to the cache 712 for quick access by the processor 710. In this way, the cache can provide a performance boost that avoids processor 710 delays while waiting for data. These and other modules can control or be configured to control the processor 710 to perform various actions. Other computing device memory 715 may be available for use as well. The memory 715 can include multiple different types of memory with different performance characteristics. The processor 710 can include any general-purpose processor and a hardware or software service stored in storage device 730 and configured to control the processor 710 as well as a special-purpose processor where software instructions are incorporated into the processor design. The processor 710 may be a self-contained system, containing multiple cores or processors, a bus, memory controller, cache, etc. A multi-core processor may be symmetric or asymmetric.

To enable user interaction with the computing device architecture 700, an input device 745 can represent any number of input mechanisms, such as a microphone for speech, a touch-sensitive screen for gesture or graphical input, keyboard, mouse, motion input, speech and so forth. An output device 735 can also be one or more of a number of output mechanisms known to those of skill in the art, such as a display, projector, television, speaker device. In some instances, multimodal computing devices can enable a user to provide multiple types of input to communicate with the computing device architecture 700. The communication interface 740 can generally govern and manage the user input and computing device output. There is no restriction on operating on any particular hardware arrangement and therefore the basic features here may easily be substituted for improved hardware or firmware arrangements as they are developed.

Storage device 730 is a non-volatile memory and can be a hard disk or other types of computer readable media which can store data that are accessible by a computer, such as magnetic cassettes, flash memory cards, solid state memory devices, digital versatile disks, cartridges, random access memories (RAMs) 725, read only memory (ROM) 720, and hybrids thereof. The storage device 730 can include software, code, firmware, etc., for controlling the processor 710. Other hardware or software modules are contemplated. The storage device 730 can be connected to the computing device connection 705. In one aspect, a hardware module that performs a particular function can include the software component stored in a computer-readable medium in connection with the necessary hardware components, such as the processor 710, connection 705, output device 735, and so forth, to carry out the function.

The term “computer-readable medium” includes, but is not limited to, portable or non-portable storage devices, optical storage devices, and various other mediums capable of storing, containing, or carrying instruction(s) and/or data. A computer-readable medium may include a non-transitory medium in which data can be stored and that does not include carrier waves and/or transitory electronic signals propagating wirelessly or over wired connections. Examples of a non-transitory medium may include, but are not limited to, a magnetic disk or tape, optical storage media such as compact disk (CD) or digital versatile disk (DVD), flash memory, memory or memory devices. A computer-readable medium may have stored thereon code and/or machine-executable instructions that may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc. may be passed, forwarded, or transmitted via any suitable means including memory sharing, message passing, token passing, network transmission, or the like.

In some embodiments the computer-readable storage devices, mediums, and memories can include a cable or wireless signal containing a bit stream and the like. However, when mentioned, non-transitory computer-readable storage media expressly exclude media such as energy, carrier signals, electromagnetic waves, and signals per se.

Specific details are provided in the description above to provide a thorough understanding of the embodiments and examples provided herein. However, it will be understood by one of ordinary skill in the art that the embodiments may be practiced without these specific details. For clarity of explanation, in some instances the present technology may be presented as including individual functional blocks comprising devices, device components, steps or routines in a method embodied in software, or combinations of hardware and software. Additional components may be used other than those shown in the figures and/or described herein. For example, circuits, systems, networks, processes, and other components may be shown as components in block diagram form in order not to obscure the embodiments in unnecessary detail. In other instances, well-known circuits, processes, algorithms, structures, and techniques may be shown without unnecessary detail in order to avoid obscuring the embodiments.

Individual embodiments may be described above as a process or method which is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

Processes and methods according to the above-described examples can be implemented using computer-executable instructions that are stored or otherwise available from computer-readable media. Such instructions can include, for example, instructions and data which cause or otherwise configure a general-purpose computer, special purpose computer, or a processing device to perform a certain function or group of functions. Portions of computer resources used can be accessible over a network. The computer executable instructions may be, for example, binaries, intermediate format instructions such as assembly language, firmware, source code. Examples of computer-readable media that may be used to store instructions, information used, and/or information created during methods according to described examples include magnetic or optical disks, flash memory, USB devices provided with non-volatile memory, networked storage devices, and so on.

Devices implementing processes and methods according to these disclosures can include hardware, software, firmware, middleware, microcode, hardware description languages, or any combination thereof, and can take any of a variety of form factors. When implemented in software, firmware, middleware, or microcode, the program code or code segments to perform the necessary tasks (e.g., a computer-program product) may be stored in a computer-readable or machine-readable medium. A processor(s) may perform the necessary tasks. Typical examples of form factors include laptops, smart phones, mobile phones, tablet devices or other small form factor personal computers, personal digital assistants, rackmount devices, standalone devices, and so on. Functionality described herein also can be embodied in peripherals or add-in cards. Such functionality can also be implemented on a circuit board among different chips or different processes executing in a single device, by way of further example.

The instructions, media for conveying such instructions, computing resources for executing them, and other structures for supporting such computing resources are example means for providing the functions described in the disclosure.

In the foregoing description, aspects of the application are described with reference to specific embodiments thereof, but those skilled in the art will recognize that the application is not limited thereto. Thus, while illustrative embodiments of the application have been described in detail herein, it is to be understood that the disclosed concepts may be otherwise variously embodied and employed, and that the appended claims are intended to be construed to include such variations, except as limited by the prior art. Various features and aspects of the above-described application may be used individually or jointly. Further, embodiments can be utilized in any number of environments and applications beyond those described herein without departing from the broader spirit and scope of the specification. The specification and drawings are, accordingly, to be regarded as illustrative rather than restrictive. For the purposes of illustration, methods were described in a particular order. It should be appreciated that in alternate embodiments, the methods may be performed in a different order than that described.

One of ordinary skill will appreciate that the less than (“<”) and greater than (“>”) symbols or terminology used herein can be replaced with less than or equal to (“≤”) and greater than or equal to (“≥”) symbols, respectively, without departing from the scope of this description.

Where components are described as being “configured to” perform certain operations, such configuration can be accomplished, for example, by designing electronic circuits or other hardware to perform the operation, by programming programmable electronic circuits (e.g., microprocessors, or other suitable electronic circuits) to perform the operation, or any combination thereof.

The phrase “coupled to” refers to any component that is physically connected to another component either directly or indirectly, and/or any component that is in communication with another component (e.g., connected to the other component over a wired or wireless connection, and/or other suitable communication interface) either directly or indirectly.

While the foregoing shows illustrative aspects of the present disclosure, it should be noted that various changes and modifications could be made herein without departing from the scope defined by the appended claims. The functions, steps and/or actions of the method claims in accordance with the aspects of the present disclosure described herein need not be performed in any particular order. Furthermore, although elements of the disclosure may be described or claimed in the singular, the plural is contemplated unless limitation to the singular is explicitly stated.

Claim language or other language reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, or A and B and C. The language “at least one of” a set and/or “one or more” of a set does not limit the set to the items listed in the set. For example, claim language reciting “at least one of A and B” or “at least one of A or B” can mean A, B, or A and B, and can additionally include items not listed in the set of A and B.

What is claimed is:

1. A method comprising:
transmitting acoustic signals through a battery cell via one or more first transducers;
receiving response signals in response to the acoustic signals at one or more second transducers; and
determining a cycle life performance score for the battery cell based on at least the response signals, the score indicating an estimated number of charge-discharge cycles that the battery cell will go through prior to reaching a threshold capacity.

2. The method of claim 1, further comprising:
determining one or more acoustic metrics indicative of one or more physical characteristics of the battery cell using the response signals.

3. The method of claim 2, wherein the cycle life performance score is determined using a trained machine learning model.

4. The method of claim 3, wherein the trained machine learning model receives, as input, at least the one or more acoustic metrics and provides, as output, the cycle life performance score.

5. The method of claim 3, wherein the machine learning further receives, as input, at least one score, the at least one score being indicative of a physical quality of the battery cell after completion of at least one stage of a battery manufacturing process.

6. The method of claim 5, wherein the at least one score includes one or more of:
a wetting score indicative of a soaking quality of the battery cell;
a Solid Electrode Interphase (SEI) score indicative of a quality of SEI formation in the battery cell;
an aging score indicative of a quality of aging of the battery cell; and
a defect score indicative of presence of at least one physical defect in the battery cell.

7. The method of claim 3, wherein the trained machine learning model further receives, as input, ground truth information on measured cycle life of one or more defect free battery cells corresponding to the battery cell.

8. The method of claim 2, wherein the one or more acoustic metrics include:
localized material inhomogeneity;
a ratio of structured material;
a degree of acoustic similarity between the response signals;
spread of acoustic character of the response signals; and
spatial variation in material structure.

9. The method of claim 1, wherein the acoustic signals are transmitted across a number of different locations of the battery cell.

10. The method of claim 1, further comprising:
outputting the cycle life performance score on a graphical user interface.

11. A battery inspection system, comprising:
a plurality of transducers; and
a controller communicatively coupled to the plurality of transducers, the controller being configured to:
send one or more commands to a first subset of the plurality of transducers for transmitting acoustic signals through a battery cell;
receive, from a second subset of the plurality of transducers, response signals in response to the acoustic signals transmitted through the battery cell; and
determine a cycle life performance score for the battery cell based on at least the response signals, the score indicating an estimated number of charge-discharge cycles that the battery cell will go through prior to reaching a threshold retention capacity.

12. The battery inspection system of claim 11, wherein the controller is further configured to determine one or more acoustic metrics indicative of one or more physical characteristics of the battery cell using the response signals.

13. The battery inspection system of claim 12, wherein the cycle life performance score is determined using a trained machine learning model.

14. The battery inspection system of claim 13, wherein the trained machine learning model receives, as input, at least the one or more acoustic metrics and provides, as output, the cycle life performance score.

15. The battery inspection system of claim 13, wherein the machine learning further receives, as input, at least one score, the at least one score being indicative of a physical quality of the battery cell after completion of at least one stage of a battery manufacturing process.

16. The battery inspection system of claim 15, wherein the at least one score includes one or more of:
a wetting score indicative of a soaking quality of the battery cell;
a Solid Electrode Interphase (SEI) score indicative of a quality of SEI formation in the battery cell;
an aging score indicative of a quality of aging of the battery cell; and
a defect score indicative of presence of at least one physical defect in the battery cell.

17. The battery inspection system of claim 13, wherein the trained machine learning model further receives, as input, ground truth information on measured cycle life of one or more defect free battery cells corresponding to the battery cell.

18. The battery inspection system of claim 12, wherein the one or more acoustic metrics include:
localized material inhomogeneity;
a ratio of structured material;
a degree of acoustic similarity between the response signals;
spread of acoustic character of the response signals; and
spatial variation in material structure.

19. The battery inspection system of claim 11, wherein the acoustic signals are transmitted across a number of different locations of the battery cell.

20. The battery inspection system of claim 11, wherein the controller is further configured to output the cycle life performance score on a graphical user interface.
